(19) United States
(12) Patent Application Publication
(10) Pub. No.: US 2017/0012025 A1
(43) Pub. Date: Jan. 12, 2017

(54) SEMICONDUCTOR PACKAGES AND METHODS OF MANUFACTURING SEMICONDUCTOR PACKAGES

(71) Applicant: Samsung Electronics Co., Ltd., Suwon-si (KR)

(72) Inventors: Heung-Kyu KWON, Seongnam-si (KR); Jong-Kook KIM, Hwaseong-si (KR); Ji-Chul KIM, Yongin-si (KR); Byeong-Yeon CHO, Suwon-si (KR)

(73) Assignee: Samsung Electronics Co., Ltd., Suwon-si (KR)

(21) Appl. No.: 15/274,453

(22) Filed: Sep. 23, 2016

Related U.S. Application Data
(62) Division of application No. 13/756,724, filed on Feb. 1, 2013.

(30) Foreign Application Priority Data
Mar. 30, 2012 (KR) 10-2012-0033290

(51) Int. Cl. H01L 25/065; H01L 23/00; H01L 25/00; H01L 23/498; H01L 21/66; H01L 21/48

(52) U.S. Cl. CPC H01L 25/0657; H01L 22/14; H01L 21/4853; H01L 21/4857; H01L 25/50; H01L 23/49822; H01L 23/49838; H01L 24/16; H01L 24/45; H01L 24/73; H01L 2225/0651; H01L 2225/06517; H01L 2225/06555; H01L 2225/06582; H01L 2225/06596; H01L 2224/16227; H01L 2224/48157; H01L 2224/73207; H01L 2924/3511; H01L 2924/37001

(57) ABSTRACT

A semiconductor package including a mounting substrate, a first semiconductor chip mounted on an upper surface of the mounting substrate, a unit package stacked on the first semiconductor chip may be provided. The unit package includes a package substrate and a second semiconductor chip mounted on the package substrate. A plurality of bonding wires connects bonding pads of the mounting substrate and connection pads of the unit package, thereby electrically connecting the first and second semiconductor chips to each other. A molding member is provided on the mounting substrate to cover the first semiconductor chip and the unit package.

### PRIORITY STATEMENT

This application is a divisional under 35 U.S.C. §121 of U.S. application Ser. No. 13/756,724, filed Feb. 1, 2013, which claims priority under 35 U.S.C. §119 to Korean Patent Application No. 2012-33290, filed on Mar. 30, 2012 in the Korean Intellectual Property Office (KIPO), the entire contents of each of which are herein incorporated by reference.

### BACKGROUND

1. Field

Example embodiments relate to semiconductor packages and/or methods of manufacturing the same. More particularly, example embodiments relate to semiconductor packages including different kinds of semiconductor chips and methods of manufacturing the same.

2. Description of the Related Art

System-In-Package (SIP) techniques are characterized by mounting several chips of different functionalities into a single package. For example, different kinds of semiconductor chips may be stacked on a same mounting substrate to form a relatively thick semiconductor package. To manufacture such a semiconductor package, good semiconductor chips that have passed wafer test processes may be sequentially stacked to form the package. Accordingly, any failure in the stacking process will result in a non-functional final package, thus decreasing fabrication yields. that have passed test processes are stacked, this technique may increase fabrication yields. However, as the height of the package decreases, the POP package may be difficult to manufacture and fabrication failures, for instance, due to warpage may occur.

### SUMMARY

Example embodiments provide semiconductor packages having a relatively small thickness and a structure capable of improving fabrication yields.

Example embodiments provide methods of manufacturing the semiconductor packages.

According to an example embodiment, a semiconductor package includes a mounting substrate, a first semiconductor chip mounted on an upper surface of the mounting substrate, a unit package stacked on the first semiconductor chip, the unit package including a package substrate and a second semiconductor chip mounted on the package substrate, a plurality of bonding wires connecting bonding pads of the mounting substrate and connection pads of the unit package to electrically connect the first and second semiconductor chips to each other, and a molding member provided on the mounting substrate to cover the first semiconductor chip and the unit package.

The first semiconductor chip may be mounted on the mounting substrate such that an active surface of the first semiconductor chip faces the upper surface of the mounting substrate.

The first semiconductor chip may be mounted on the mounting substrate by a flip chip process.

The molding member may cover at least a side portion of the mounting substrate.

The unit package may be stacked on the first semiconductor chip using an adhesive layer such that a lower surface of the package substrate is exposed.

The bonding pads may be arranged on the upper surface of the mounting substrate and the connection pads are arranged on the exposed lower surface of the package substrate.

The bonding pads of the mounting substrate may include data signal_bonding pads and control signal_bonding pads, and the data signal_bonding pads and the control signal_bonding pads may be arranged along a side portion of the mounting substrate.

The mounting substrate may include a multi-layered printed circuit board including inner circuit layers formed therein, a data signal_conductive pattern may be formed in the inner circuit layers to electrically connect at least one of the data signal_bonding pad and the first semiconductor chip and to transmit a data signal between the first and secondsemiconductor chips, and a control signal_conductive pattern may be formed in a same of the inner circuit layers to electrically connect at least one of the control signal_bonding pads and the first semiconductor chip, and to transmit a control signal between the first and second semiconductor chips.

The mounting substrate may further include a metal core layer and the metal core layer may be interposed between the inner circuit layers.

The connection pads of the package substrate may include data signal_connection pads and control signal_connection pads, and the data signal_connection pads and the control signal_connection pads may be arranged along a side portion of the package substrate corresponding to the data signal_bonding pads and the control signal_bonding pads.

According to an example embodiment, a method of manufacturing a semiconductor package includes mounting a first semiconductor chip on an upper surface of a mounting substrate to form a preliminary package, testing the preliminary package, stacking a unit package on the first semiconductor chip, the unit package including a package substrate and a second semiconductor chip mounted on the package substrate, connecting bonding pads of the mounting substrate and connection pads of the unit package using a plurality of bonding wires to electrically connect the first and second semiconductor chips to each other, and forming a molding member on the mounting substrate to cover the first semiconductor chip and the unit package.

If the preliminary package passes the testing, the stacking a unit package on the first semiconductor chip may be performed.

The stacking a unit package on the first semiconductor chip may include adhering a plurality of the preliminary packages on a carrier frame, and stacking a plurality of unit packages on the preliminary packages, respectively.

The molding member may cover at least a side portion of the mounting substrate.

The bonding pads of the mounting substrate may include data signal_bonding pads and control signal_bonding pads, and the data signal_bonding pads and the control signal_bonding pads may be arranged along a side portion of the mounting substrate.

According to an example embodiment, a semiconductor package includes a mounting substrate having a multi-layered structure, the mounting substrate including a circuit layer, the circuit layer including a data signal_conductive pattern and a control signal_conductive pattern, a semiconductor chip on the mounting substrate, and a unit package on the semiconductor chip. The unit package is electrically connected to the semiconductor chip to transmit a data signal and a control signal via the respective data signal_conductive pattern and control signal_conductive pattern in the circuit layer.

The semiconductor package may further include data signal_connection pads and control signal_connection pads on the unit package, and data signal_bonding pads and control signal_bonding pads on the mounting substrates. The data signal_bonding pads and control signal_bonding pads may be arranged along a side portion of the mounting substrate, data signal_bonding pads and control signal_bonding pads may be electrically connected to the semiconductor chip via the data signal_conductive pattern and control signal_conductive pattern, and the data signal_bonding pads and control signal_bonding pads may be electrically connected to the data signal_connection pads and control signal_connection pads.

The circuit layer may bein an upper layer of the multi-layered structure.

The multi-layered structure may include at least three layers and a power conductive pattern for transmitting a power voltage is in a middle layer of the at least three layers.

The multi-layered structure includes at least three layers and a middle layer of the at least three layers may be a metal core layer, which serves as a ground wiring layer.

According to example embodiments, after a first semiconductor chip is mounted on a mounting substrate to from a preliminary package, the preliminary packages may be tested to determine whether or not the preliminary package is defective. Then, a unit package having a second semiconductor chip may be stacked on the good preliminary package, e.g., passes the test, to form a semiconductor package.

Further, data signal_bonding pads and control signal_bonding pads of bonding pads of the mounting substrate may be arranged along one side portion of the mounting substrate. A data signal_conductive pattern and a control signal_conductive pattern may be formed in the same inner circuit layer of multi-layered inner circuit layers to transmit a data signal and a control signal.

Thus, the structure of the mounting substrate may be simplified and the thickness of the semiconductor package may be reduced. Further, a failure rate of final products may be reduced, thereby improving fabrication yields of semiconductor packages and reducing manufacturing costs.

### BRIEF DESCRIPTION OF THE DRAWINGS

Example embodiments will be more clearly understood from the following detailed description taken in conjunction with the accompanying drawings. FIGS. 1 to 14 represent non-limiting, example embodiments as described herein.

FIG. 1 is a cross-sectional view illustrating a semiconductor package in accordance with an example embodiment.

FIG. 2 is a plan view illustrating the semiconductor package of FIG. 1.

FIG. 3 is a plan view illustrating a first semiconductor chip mounted on a mounting substrate in the semiconductor package of FIG. 1.

FIG. 4 is a plan view illustrating an inner circuit layer of the mounting substrate of FIG. 1.

FIG. 5 is a cross-sectional view taken along the line V-V′ of FIG. 4.

FIG. 6 is a cross-sectional view taken along the line VI-VI′ of FIG. 4.

FIG. 7 is a flow chart illustrating a method of manufacturing the semiconductor package of FIG. 1.

FIGS. 8 to 13 are cross-sectional views illustrating a method of manufacturing a semiconductor package in accordance with an example embodiment.

FIG. 14 is a block diagram illustrating an electronic device including the semiconductor package of FIG. 1.

### DETAILED DESCRIPTION OF EXAMPLE EMBODIMENTS

Various example embodiments will be described more fully hereinafter with reference to the accompanying drawings, in which example embodiments are shown. Example embodiments may, however, be embodied in many different forms and should not be construed as limited to example embodiments set forth herein. Rather, these example embodiments are provided so that this disclosure will be thorough and complete, and will fully convey the scope of example embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

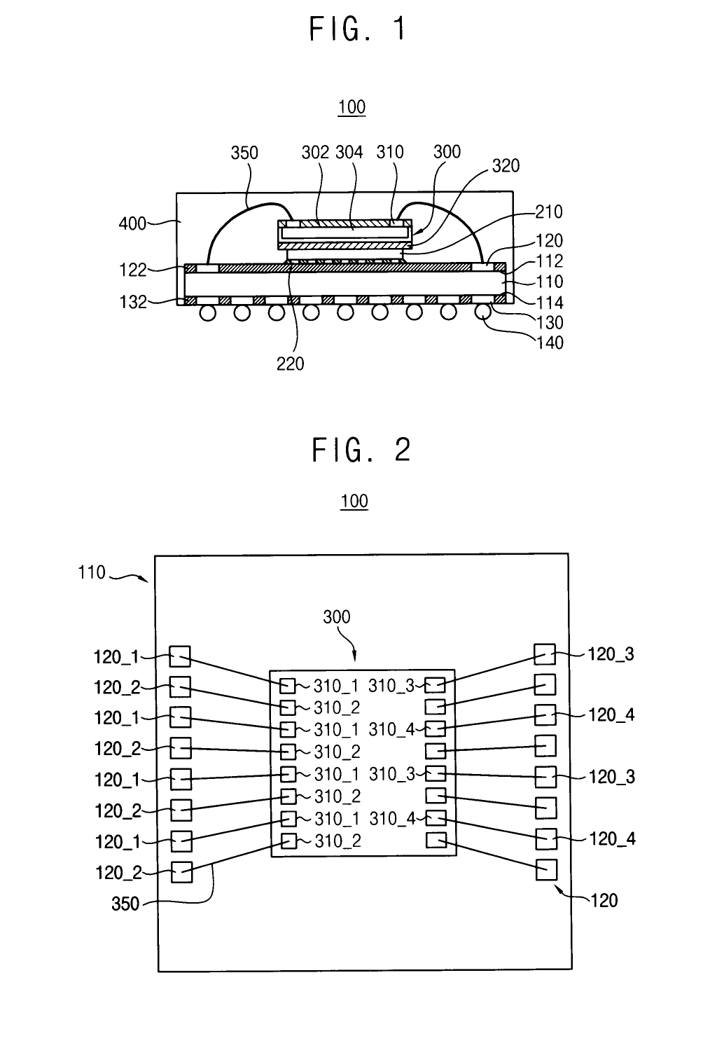

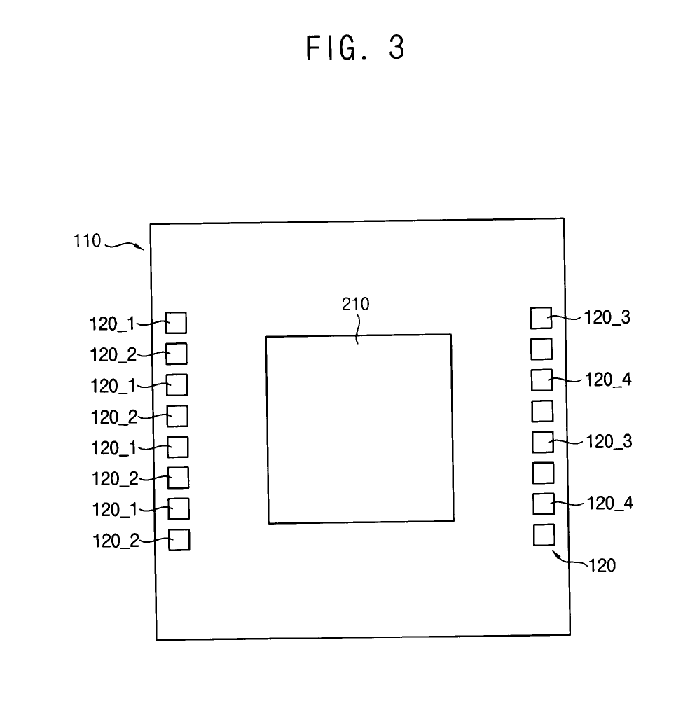

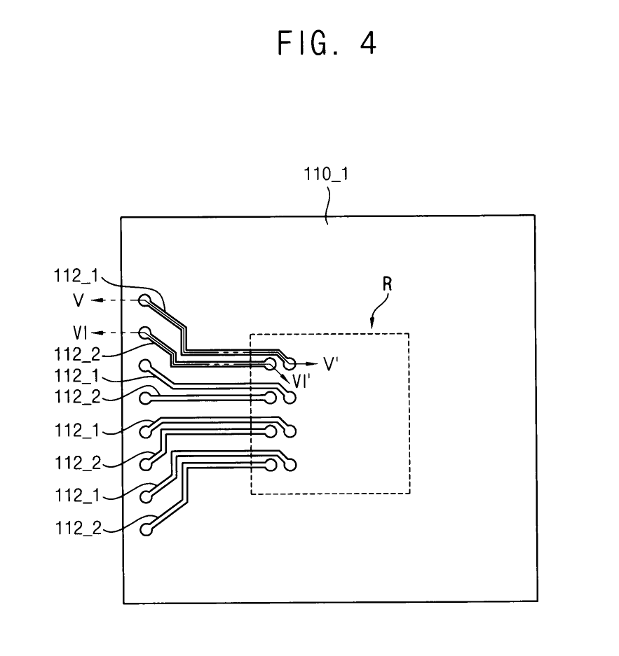

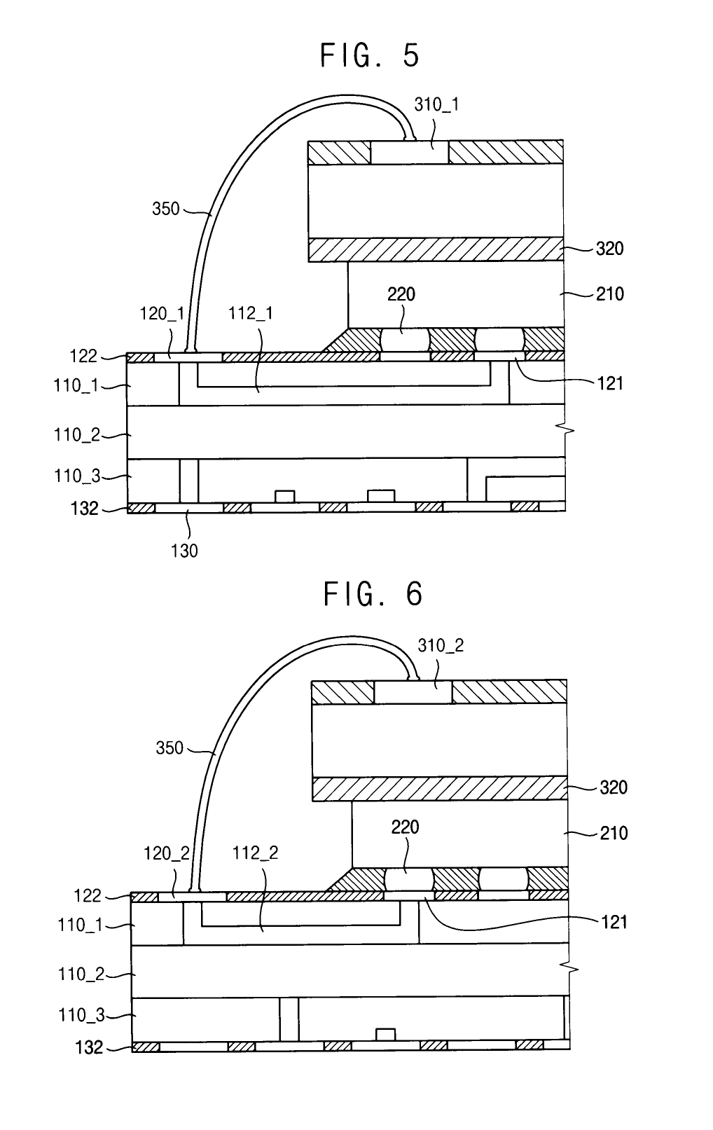

FIG. 1 is a cross-sectional view illustrating a semiconductor package in accordance with an example embodiment. FIG. 2 is a plan view illustrating the semiconductor package of FIG. 1. FIG. 3 is a plan view illustrating a first semiconductor chip mounted on a mounting substrate in the semiconductor package of FIG. 1. FIG. 4 is a plan view illustrating an inner circuit layer of the mounting substrate of FIG. 1. FIG. 5 is a cross-sectional view taken along the line V-V′ of FIG. 4. FIG. 6 is a cross-sectional view taken along the line VI-VI′ of FIG. 4.

Referring to FIGS. 1 to 6, a semiconductor package 100 according to an example embodiments includes a mounting substrate 110, a first semiconductor chip 210, a unit package 300 including a second semiconductor chip 304, a plurality of bonding wires 350 electrically connecting the first semiconductor chip 210 and the unit package 300, and a molding member 400 covering the first semiconductor chip 210 and the unit package 300.

According to an example embodiment, the mounting substrate 110 may be a substrate having an upper surface 112 and a lower surface 114 opposite to each other. For example, the mounting substrate 110 may be a printed circuit board (PCB). The PCB may be a multi-layered circuit board having various circuits and vias therein.

The first semiconductor chip 210 may be mounted on the upper surface 112 of the mounting substrate 110. As illustrated in FIG. 4, the mounting substrate 110 may have a mounting region (R) for the first semiconductor chip 210. At least one first semiconductor chip may be mounted on the mounting substrate 110, however, the number of the first semiconductor chips mounted on the substrate should not be limited thereto.

Bonding pads 120 for electrical connection with the second semiconductor chip 304 may be formed on the upper surface 112 of the mounting substrate 110. The bonding pads 120 may be arranged on a peripheral region outside the mounting region (R). Terminal pads 121 for electrical connection with the first semiconductor chip 210 may be formed on the upper surface 112 of the mounting substrate 110. The terminal pads 121 may be arranged within the mounting region (R).

Outer connection pads 130 may be formed on the lower surface 114 of the mounting substrate 110 such that an electrical signal may be inputted/outputted to/from the semiconductor chip through the outer connection pads 130. For example, the bonding pads 120, the terminal pads 121 and the outer connection pads 130 may be exposed by insulation layer patterns 122 and 132. The insulation layer pattern may include silicon oxide, silicon nitride, silicon oxynitride, etc.

Some of the boding pads and the terminal pads may be electrically connected to the outer connection pads 130 on the lower surface of the mounting substrate 110 by inner wirings (conductive patterns) of the mounting substrate 110.

A connection member 140 for electrical connection with an external device may be disposed on the outer connection pad 130. For example, the connection member 140 may be a solder ball or a solder bump.

According to an example embodiment, the first semiconductor chip 210 may be mounted on the mounting substrate 110 such that an active surface of the first semiconductor chip 210 faces the upper surface of the mounting substrate 110. For example, the first semiconductor chip 210 may be mounted by a flip chip bonding process. The first semiconductor chip 210 may be electrically connected to the mounting substrate 110 by bumps 220.

The unit package 300 may be stacked on the first semiconductor chip 210. For example, the unit package 300 may be adhered to the first semiconductor chip 210 by an adhesive layer 320. The unit package 300 may include a package substrate 302 and a second semiconductor chip 304 mounted on the package substrate 302. The unit package 300 may include at least one second semiconductor chip, however, the number of the mounted second semiconductor chips should not be limited thereto.

For example, the unit package 300 may be stacked on the first semiconductor chip 210 by the adhesive layer 320 such that a lower surface of the package substrate 302 may be exposed upward. Connection pads 310 for electrical connection with the boding pads 120 of the mounting substrate 110 may be formed on the exposed lower surface of the package substrate 302.

The unit package 300 may be electrically connected to the mounting substrate 110 by a plurality of bonding wires 350. The bonding wires 350 may be drawn from the bonding pads 120 to be connected to the connection pads 310 of the package substrate 302, respectively. Accordingly, the first semiconductor chip 210 may be electrically connected to the second semiconductor chip 304 by the bonding wires 350.

The molding member 400 may be formed on the upper surface of the mounting substrate 110 to protect the first semiconductor chip 210 and the unit package 300 from the outside. The molding member 400 may include epoxy mold compound (EMC). Additionally, the molding member 400 may be formed to cover at least side portion of the mounting substrate 110.

For example, the semiconductor package 100 may be a System-In-Package (SIP). The first semiconductor chip 210 may be a logic chip including a logic circuit. The second semiconductor chip 304 may be a memory chip including a memory circuit. The memory circuit may include a memory cell region for storing data and/or a memory logic region for operating the memory chip.

The first semiconductor chip 210 may include a circuit portion having functional circuits. The functional circuits may include a transistor or a passive device, e.g., resistance, capacitor, etc. The functional circuits may include a memory control circuit, an external input/output circuit, a micro input/output circuit and/or an additional functional circuit, etc. The memory control circuit may provide a data signal and/or a memory control signal for operating the second semiconductor chip 304. For example, the memory control signal may include address signal, command signal, or clock signal.

The bonding wires 350 may be used as an electrical path for transmitting a signal or power required to operate the second semiconductor chip 304. The signal may include a data signal and/or a control signal. The power may include a power voltage (VDD) and a ground voltage (VSS). The bonding wires 350 may be connected to the bonding pads 120 of the mounting substrate 110, respectively.

Accordingly, the data signal and/or the control signal may be transmitted from the memory control circuit of the first semiconductor chip 210 to the second semiconductor chip 304. The power voltage (VDD) and/or the ground voltage (VSS) may be supplied to the second semiconductor chip 304 through the mounting substrate 110.

As illustrated in FIGS. 2 and 3, the bonding pads 120 of the mounting substrate 110 may include data signal_bonding pads 120_1 and control signal_bonding pads 120_2. The bonding pads 120 of the mounting substrate 110 may include power voltage_bonding pads 120_3 and ground voltage_bonding pads 120_4.

The data signal_bonding pads 120_1 and the control signal_bonding pads 120_2 may be arranged in a first side portion of the mounting substrate 110. For example, the data signal_bonding pads 120_1 and the control signal_bonding pads 120_2 may be arranged along the first side portion of the mounting substrate 110. For example, the data signal_bonding pads 120_1 and the control signal_bonding pads 120_2 may be arranged asymmetric on the mounting substrate 110. The power voltage_bonding pads 120_3 and the ground voltage_bonding pads 120_4 may be arranged in a second side portion opposite to the first side portion of the mounting substrate 110. The first semiconductor chip 210 may be arranged between the first and second side portions of the mounting substrate 110.

The connection pads 310 of the package substrate 302 may include data signal_connection pads 310_1 and control signal_connection pads 310_2. The connection pads 310 of the package substrate 302 may include power voltage_connection pads 310_3 and the ground voltage_connection pads 310_4.

The data signal_connection pads 310_1 and the control signal_connection pads 310_2 may be arranged in a first side portion of the package substrate 302 corresponding to the bonding pads 120_1 and 120_2 of the mounting substrate 110. The power voltage_connection pads 310_3 and the ground voltage_connection pads 310_4 may be arranged in a second side portion opposite to the first side portion of the mounting substrate 110.

According to an example embodiment, the mounting substrate 110 may include at least two inner circuit layers. For example, the number of the inner circuit layers of the mounting substrate 110 may be two, four or six. Conductive patterns for transmitting the data signal, the control signal, the power voltage (VDD) and the ground voltage (VSS) may be formed in the inner circuit layers. Additionally, the package substrate 302 of the unit package 300 may include at least two inner circuit layers. For example, the number of the inner circuit layers of the package substrate 302 may be two, four or six.

As illustrated in FIGS. 4 to 6, the mounting substrate 110 may include a first inner circuit layer 110_1, a metal core layer 110_2 and a second inner circuit layer 110_3. The metal core layer 110_2 may be interposed between the first inner circuit layer 110_1 and the second inner circuit layer 110_3.

Conductive patterns 112_1 and 112_2 for transmitting the data signal and the control signal may be formed in the first inner circuit layer 110_1. The data signal_conductive pattern 112_1 may be formed in the first inner circuit layer 110_1 to electrically connect the data signal_bonding pad 120_1 to the corresponding bump 220. The control signal_conductive pattern 112_2 may be formed in the first circuit layer 110_1 to electrically connect the control signal_bonding pad 120_2 to the corresponding bump 220.

Although it is not illustrated in the figure, conductive patterns for transmitting the power voltage (VDD) may be formed in the second inner circuit layer 110_2. The metal core layer 110_2 may be used as a ground wiring layer.

The bonding wires 350 may be drawn from the data signal_bonding pad 120_1 of the mounting substrate 110 to be connected to the data signal_connection pad 310_1 of the package substrate 302. The bonding wires 350 may be drawn from the control signal_bonding pad 120_2 of the mounting substrate 110 to be connected to the data signal_connection pad 310_2 of the package substrate 302.

Accordingly, the data signal and the control signal may be transferred from the first semiconductor chip 210 to the second semiconductor chip 304 through the first inner circuit layer 110_1 of the mounting substrate 110 and the bonding wires 350.

The bonding wires 350 may be drawn from the power voltage_bonding pad 120_3 of the mounting substrate 110 to be connected to the power voltage_connection pad 310_3 of the package substrate 302. The bonding wires 350 may be drawn from the ground voltage_bonding pad 120_4 of the mounting substrate 110 to be connected to the ground voltage_connection pad 310_4 of the package substrate 302. Accordingly, the power voltage (VDD) and the ground voltage (VSS) may be supplied to the second semiconductor chip 340 through the mounting substrate 110 and the bonding wires 350.

According to an example embodiment, the data signal_bonding pads 120_1 and the control signal_bonding pads 120_2 may be arranged in the first side portion of the mounting substrate 110. The data signal_connection pads 310_1 and the control signal_connection pads 310_2 may be arranged in the first side portion of the package substrate 302 corresponding to the bonding pads 120_1 and 120_2 of the mounting substrate 110.

Accordingly, as illustrated in FIG. 4, the data signal_conductive pattern 112_1 and the control signal_conductive pattern 112_2 may be formed in the same inner circuit layer, to transmit the data signal and the control signal. Thus, the number of the inner circuit layers may be decreased, thereby reducing the thickness of the mounting substrate 110.

After the first semiconductor chip 210 is mounted on the mounting substrate 110 to form a preliminary package, the preliminary package may be tested. The unit package 300 may be stacked on the preliminary package that has passed the test, to complete the semiconductor package 100.

Thus, the structure of the mounting substrate 110 may be simplified and the thickness of the semiconductor package 100 may be reduced. Further, defective failure rate of final products may be reduced, thereby improving fabrication yields of semiconductor packages and reducing manufacturing costs.

Hereinafter, a method of manufacturing the semiconductor package of FIG. 1 will be explained.

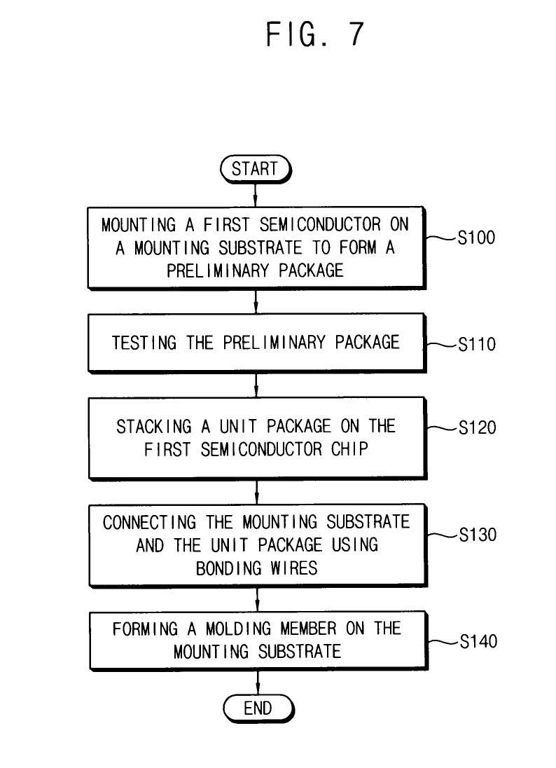

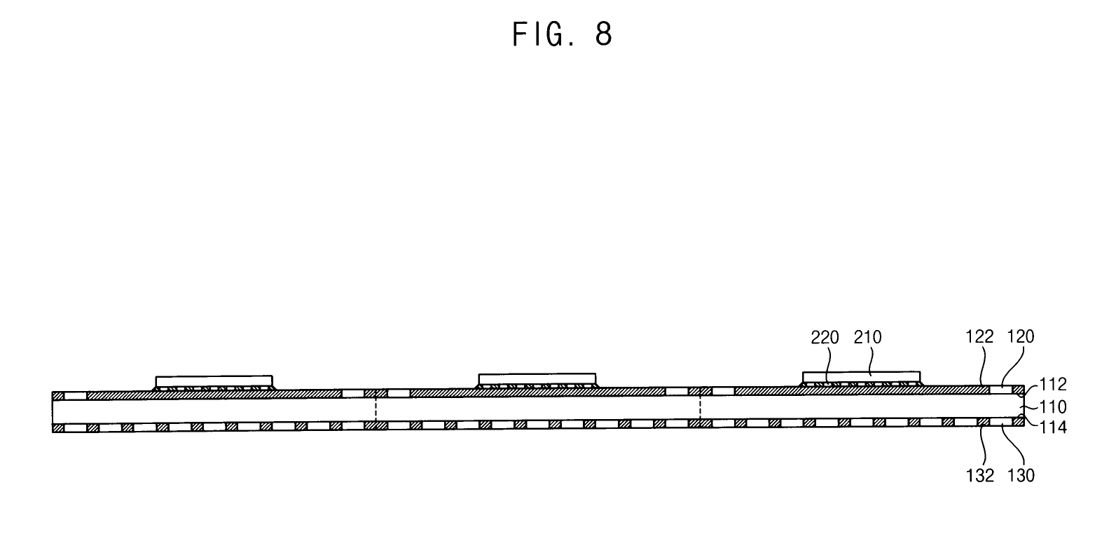

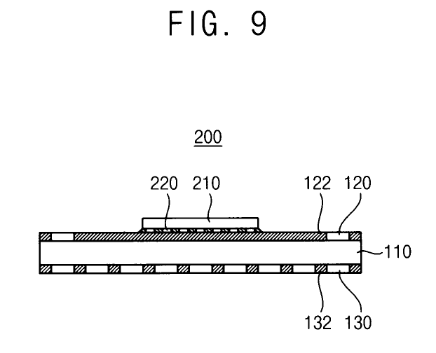

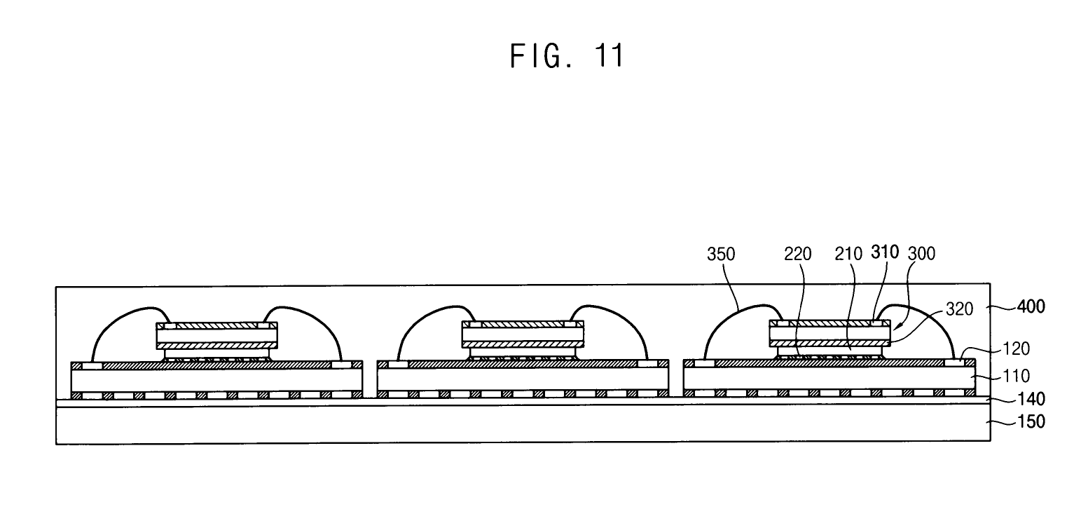

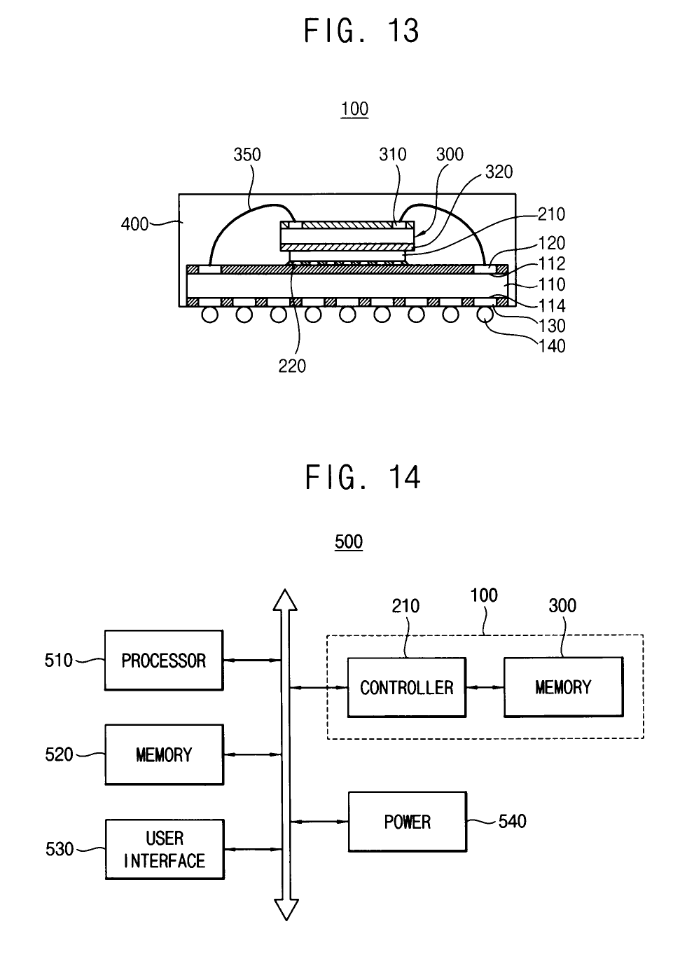

FIG. 7 is a flow chart illustrating a method of manufacturing the semiconductor package of FIG. 1. FIGS. 8 to 13 are cross-sectional views illustrating a method of manufacturing a semiconductor package in accordance with an example embodiment.

Referring to FIGS. 7 to 9, a first semiconductor chip 210 may be mounted on an upper surface 112 of a mounting substrate 110 to form a preliminary package 200 (S100), and the preliminary package 200 may be tested (S110).

According to an example embodiment, the mounting substrate 110 may be a printed circuit board (PCB) having an upper surface 112 and a lower surface 114 opposite to each other. The PCB may be a multi-layered circuit board having various circuits and vias therein.

A plurality of bonding pads 120 may be formed on the upper surface 112 of the mounting substrate 110. A plurality of outer connection pads 130 may be formed on the lower surface 114 of the mounting substrate 110.

The bonding pads 120 and the outer connection pads 130 may be exposed by insulation patterns 122 and 132. The insulation layer pattern may include silicon oxide, silicon nitride, silicon oxynitride, etc.

Some of the boding pads 120 may be electrically connected to the outer connection pads 130 on the lower surface of the mounting substrate 110 by inner wirings (conductive patterns) of the mounting substrate 110.

As illustrated in FIG. 8, a plurality of the first semiconductor chips 210 may be mounted on the mounting substrate 110. For example, the first semiconductor chip 210 may be mounted by a flip chip bonding process. The first semiconductor chip 210 may be mounted on the mounting substrate 110 such that an active surface of the first semiconductor chip 210 faces the upper surface 112 of the mounting substrate 110. The first semiconductor chip 210 may be electrically connected to the mounting substrate 110 by bumps 220.

Referring again to FIG. 3, the bonding pads 120 of the mounting substrate 110 may include data signal_bonding pads 120_1 and control signal_bonding pads 120_2. Additionally, the bonding pads 120 of the mounting substrate 110 may include power voltage_bonding pads 120_3 and ground voltage_bonding pads 120_4.

The data signal_bonding pads 120_1 and the control signal_bonding pads 120_2 may be arranged in a first side portion of the mounting substrate 110. For example, the data signal_bonding pads 120_1 and the control signal_bonding pads 120_2 may be arranged along the first side portion of the mounting substrate 110. The power voltage_bonding pads 120_3 and the ground voltage_bonding pads 120_4 may be arranged in a second side portion opposite to the first side portion of the mounting substrate 110.

After the mounting substrate 110 having the first semiconductor chips is cut (or alternatively, severed, separated, or singulated) by a router process to form the preliminary package 200, an inspection process may be performed on the preliminary packages 200.

According to an example embodiment, a test signal may be applied to the preliminary package 200 to inspect or determine whether or not the preliminary package 200 is defective. When the preliminary package turns out to be good, e.g., passes the test, a unit package may be stacked on the good preliminary package.

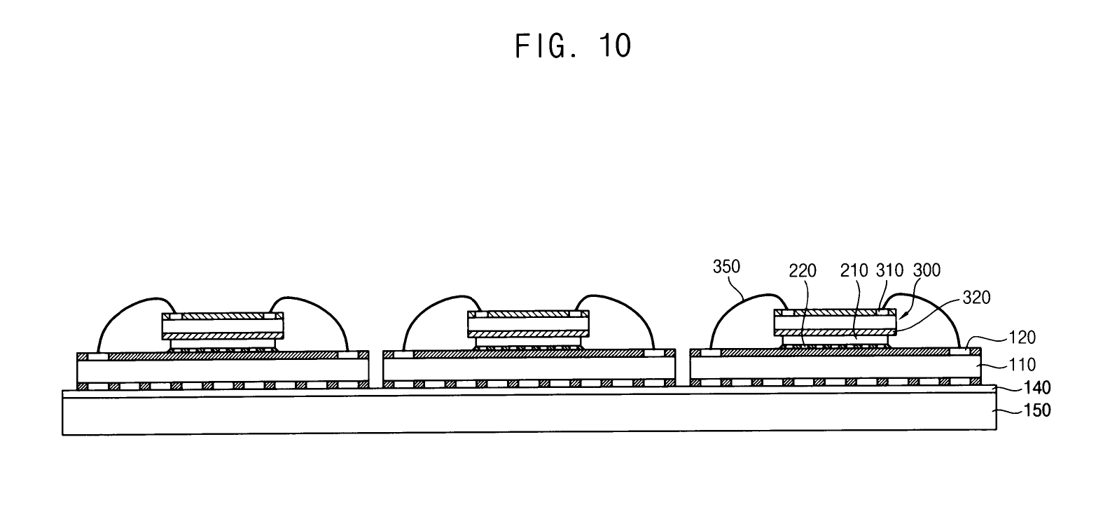

Referring to FIGS. 7 and 10, a unit package 300 may be stacked on the first semiconductor chip 210 of the good preliminary package 200 (S120), and the unit package 300 may be electrically connected to the mounting substrate 110 by a plurality of bonding wires 350 (S130).

According to an example embodiment, the good preliminary packages may be adhered to a carrier frame 150 using a first adhesive layer 140, and a plurality of the unit packages 300 may be stacked on the good preliminary packages 200, respectively.

The unit package 300 may be stacked on the first semiconductor chip 210 of the good preliminary package 200 by a second adhesive layer 320. As illustrated in FIG. 1, the unit package 300 may include a package substrate 302 and a second semiconductor chip 304 mounted on the package substrate 302. The unit package 300 may include at least one second semiconductor chip, however, the number of the mounted second semiconductor chips should not be limited thereto.

The unit package 300 may be stacked on the first semiconductor chip 210 by the second adhesive layer 320 such that a lower surface of the package substrate 302 may be exposed upward. Connection pads 310 for electrical connection with the boding pads 120 of the mounting substrate 110 may be formed on the exposed lower surface of the package substrate 302.

The unit package 300 may be electrically connected to the mounting substrate 110 by the plurality of the bonding wires 350. A wire bonding process may be performed such that the bonding wires 350 may be drawn from the bonding pads 120 of the mounting substrate 110 to be connected to the connection pads 310 of the unit package 300. Accordingly, the second semiconductor chip 304 of the unit package 300 may be electrically connected to the first semiconductor chip 210 by the bonding wires 350. Additionally, the second semiconductor chip 304 of the unit package 300 may be electrically connected to the outer connection pad 130 of the mounting substrate 110 by the bonding wires 350.

Referring again to FIG. 2, the connection pads 310 of the package substrate 302 may include data signal_connection pads 310_1 and control signal_connection pads 310_2. Additionally, the connection pads 310 of the package substrate 302 may include power voltage_connection pads 310_3 and the ground voltage_connection pads 310_4.

The bonding wire 350 may be drawn from the data signal_bonding pad 120_1 of the mounting substrate 110 to be connected to the data signal_connection pad 310_1 of the package substrate 302. The bonding wire 350 may be drawn from the control signal_bonding pad 120_2 of the mounting substrate 110 to be connected to the data signal_connection pad 310_2 of the package substrate 302.

Additionally, the bonding wire 350 may be drawn from the power voltage_bonding pad 120_3 of the mounting substrate 110 to be connected to the power voltage_connection pad 310_3 of the package substrate 302. The bonding wire 350 may be drawn from the ground voltage_bonding pad 120_4 of the mounting substrate 110 to be connected to the ground voltage_connection pad 310_4 of the package substrate 302.

As illustrated in FIGS. 4 to 6, a data signal_conductive pattern 112_1 and a control signal_conductive pattern 112_2 may be formed in the first inner circuit layer 110_1 of the mounting substrate 110. Accordingly, a data signal and a control signal may be transferred from the first semiconductor chip 210 to the second semiconductor chip 304 of the unit package 300 through the first inner circuit layer 110_1 of the mounting substrate 110 and the bonding wires 350.

Referring to FIGS. 7 and 11 to 13, a molding member 400 may be formed on the mounting substrate 110 to cover the first semiconductor chip 210 and the unit package 300, to form a semiconductor package 100 (S140).

According to an example embodiment, a molding layer may be coated on the upper surface of the mounting substrate 110 to form the molding member 400. For example, the molding layer may include epoxy mold compound (EMC).

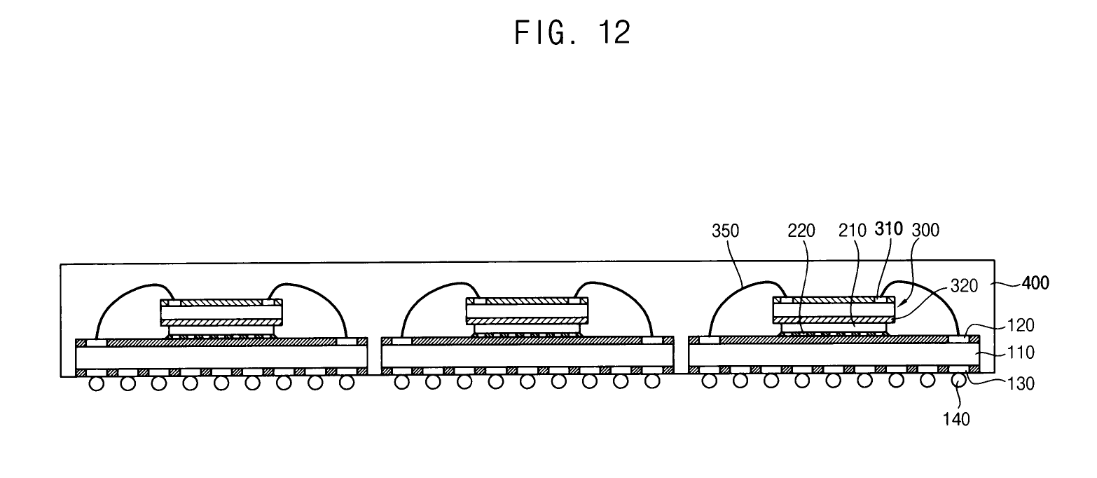

After removing a carrier frame 150, the molding layer may be cut or severed to form the semiconductor package 100. As illustrated in FIG. 12, the molding member 400 may be formed to cover at least side portion of the mounting substrate 110.

After the unit package 300 is stacked on the first semiconductor chip 210, a connection member 140 may be formed on the outer connection pad 130 on the lower surface of the mounting substrate 110. For example, the connection member 140 may be a solder ball or a solder bump.

The semiconductor package according to example embodiments may be applied to an electronic device such as a mobile phone. The electronic device may include a plurality of semiconductor chips for performing all or most of the functions of camera, MP3 player, digital multimedia broadcast (DMB), wireless internet, mobile banking, etc. The semiconductor package according to example embodiments may include different kinds of semiconductor chips to implement various operations in the mobile phone. The electronic device may include note book, personal multimedia player (PMP), MP3 player, memory stick, memory card, etc.

FIG. 14 is a block diagram illustrating an electronic device including the semiconductor package of FIG. 1.

Referring to FIG. 14, an electronic device 500 may include a processor 510, a first memory 520, a user interface 530, and a memory system 100, which is the semiconductor package 100 of FIG. 1.

The processor 510 may perform specific calculations or tasks. For example, the processor 510 may be a central processing unit (CPU) or a microprocessor. The processor 510 may communicate with the first memory 520 via an address bus, a control bus, a data bus, or the like.

For example, the first memory 520 may be a flash memory. The memory 520 may include dynamic random access memory (DRAM), static random access memory (SRAM), erasable programmable read-only memory (EPROM), electrically erasable programmable read-only memory (EEPROM), and flash memory device.

The processor 510 may be connected to an expanded bus, e.g., a peripheral component interconnect (PCI) bus. Accordingly, the processor 510 may control the user interface 530 including one or more input devices, e.g., a keyboard and/or mouse, and one or more output device, e.g., printer and/or display device.

Data that supplied through the user interface 530 or processed by the processor 510 may be stored in a second memory 300 through a controller 210 of the memory system 100.

The electronic device 500 may further include a power 540 for supplying an operation power. Additionally, the electronic device 500 may further include application chipset, camera image processor (CIS), mobile DRAM, etc.

As mentioned above, according to example embodiments, after a first semiconductor chip is mounted on a mounting substrate to from a preliminary package, the preliminary packages may be tested to determine whether or not the preliminary package is defective. A unit package having a second semiconductor chip may be stacked on the good preliminary package, e.g., passes the test, to form a semiconductor package.

Further, data signal_bonding pads and control signal_bonding pads of bonding pads of the mounting substrate may be arranged along one side portion of the mounting substrate. A data signal_conductive pattern and a control signal_conductive pattern may be formed in the same inner circuit layer of multi-layered inner circuit layers to transmit a data signal and a control signal.

Thus, the structure of the mounting substrate may be simplified and the thickness of the semiconductor package may be reduced. Further, a failure rate of final products may be reduced, thereby improving fabrication yields of semiconductor packages and reducing manufacturing costs.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims

What is claimed is:

1. A method of manufacturing a semiconductor package, comprising:
mounting a first semiconductor chip on an upper surface of a mounting substrate to form a preliminary package;
testing the preliminary package;
stacking a unit package on the first semiconductor chip, the unit package including a package substrate and a second semiconductor chip mounted thereon;
connecting bonding pads of the mounting substrate and connection pads of the unit package using a plurality of bonding wires to electrically connect the first and second semiconductor chips to each other; and
forming a molding member on the mounting substrate to cover the first semiconductor chip and the unit package.

2. The method of claim 1, wherein if the preliminary package passes the testing, the stacking a unit package on the first semiconductor chip is performed.

3. The method of claim 1, wherein the stacking a unit package on the first semiconductor chip comprises:
adhering a plurality of the preliminary packages on a carrier frame; and
stacking a plurality of the unit packages on the preliminary packages, respectively.

4. The method of claim 3, wherein the molding member covers at least a side portion of the mounting substrate.

5. The method of claim 1, wherein the bonding pads of the mounting substrate comprises data signal_bonding pads and control signal_bonding pads, and the data signal_bonding pads and the control signal_bonding pads are arranged along a side portion of the mounting substrate.
